(19) United States
(12) Patent Application Publication
(10) Pub. No.: US 2010/0046061 A1
(43) Pub. Date: Feb. 25, 2010

(54) Mems package having inclined surface

(76) Inventors: Hirotoshi Ichikawa, Tokyo (JP); Yoshihiro Maeda, Tokyo (JP); Fusao Ishii, Pittsburgh, PA (US)

Correspondence Address: Bo-In Lin, 13445 Mandoli Drive, Los Altos Hills, CA, 94022, US

(21) Appl. No.: 12/589,907

(22) Filed: Oct. 29, 2009

Related U.S. Application Data
(63) Continuation-in-part of application No. 12/231,922, filed on Sep. 5, 2008.
Application No. 12/231,922 is a continuation-in-part of application No. 11/121,543, filed on May 4, 2005, now Pat. No. 7,268,932.
Application No. 11/121,543 is a continuation-in-part of application No. 10/698,620, filed on Nov. 1, 2003, now abandoned.
Application No. 10/698,620 is a continuation-in-part of application No. 10/699,140, filed on Nov. 1, 2003, now Pat. No. 6,862,127.
Application No. 10/699,140 is a continuation-in-part of application No. 10/699,143, filed on Nov. 1, 2003, now Pat. No. 6,903,860.
(60) Provisional application No. 61/197,717, filed on Oct. 30, 2008.
(60) Provisional application No. 60/967,811, filed on Sep. 6, 2007.

(51) Int. Cl. G02B 26/00; H01L 21/50

(52) U.S. Cl. 359/291; 438/27; 257/E21.499

(57) ABSTRACT

An image projection system comprises a micro-electromechanical system (MEMS) package wherein the MEMS package further includes: a first substrate and a second substrate joined together at a joinder surface applied with a ponder material thereon to provide an internal space to contain and package a MEMS device therein, wherein at least one of the first and second substrate is configured to have a an inclined surface near the joinder surface.

### CROSS REFERENCE TO RELATED APPLICATIONS

This application is a non-provisional application of a Provisional Application 61/197,717 and claims a Priority Date of Oct. 30, 2008. This application is also a Continuation-in-Part (CIP) application of a co-pending application Ser. No. 12/231,922 filed on Sep. 5, 2008 by common Applicants of this patent application. The application Ser. No. 12/231,922 is a non-provisional application of a U.S. Patent Provisional Application No. 60/967,811 filed on Sep. 6, 2007. The patent application Ser. No. 12/231,922 is a Continuation In Part (CIP) application of a pending U.S. patent application Ser. No. 11/121,543 filed on May 4, 2005 issued into U.S. Pat. No. 7,268,932. The application Ser. No. 12/231,922 is also a Continuation In Part (CIP) application of three previously filed applications. These three applications are 10/698,620 filed on Nov. 1, 2003, 10/699,140 filed on Nov. 1, 2003 now issued into U.S. Pat. No. 6,862,127, and 10/699,143 filed on Nov. 1, 2003 now issued into U.S. Pat. No. 6,903,860 by the Applicant of this patent applications. The disclosures made in these patent applications are hereby incorporated by reference in this patent application.

### BACKGROUND OF THE INVENTION

1. Field of the Invention

The present invention relates generally to the configuration and methods for manufacturing an image display system implemented with a micro electromechanical system (MEMS) device functioning as a spatial light modulator (SLM). More particularly, this invention relates to a technology used for packaging a MEMS device provided with electrical connections and optical configurations suitable to operate in the image display system.

2. Description of the Related Art

After the dominance of CRT technology in the display industry for over 100 years, Flat Panel Display (FPD) and Projection Display have gained popularity because of their space efficiency and larger screen size. Projection displays using micro-display technology are gaining popularity among consumers because of their high picture quality and lower cost. There are two types of micro-displays used for projection displays in the market. One is micro-LCD (Liquid Crystal Display) and the other is micro-mirror technology. Because a micro-mirror device uses un-polarized light, it produces better brightness than micro-LCD, which uses polarized light.

Although significant advances have been made in technologies of implementing electromechanical micro-mirror devices as spatial light modulators, there are still limitations in their high quality images display. Specifically, when display images are digitally controlled, image quality is adversely due to an insufficient number of gray scales.

Electromechanical micro-mirror devices have drawn considerable interest because of their application as spatial light modulators (SLMs). A spatial light modulator requires an array of a relatively large number of micro-mirror devices. In general, the number of required devices ranges from 60,000 to several million for each SLM. Referring to FIG. 1A, an image display system 1 including a screen 2 is disclosed in a relevant U.S. Pat. No. 5,214,420. A light source 10 is used to generate light beams to project illumination for the display images on the display screen 2. The light 9 projected from the light source is further concentrated and directed toward lens 12 by way of mirror 11. Lenses 12, 13 and 14 form a beam columnator operative to columnate the light 9 into a column of light 8. A spatial light modulator 15 is controlled by a computer through data transmitted over data cable 18 to selectively redirect a portion of the light from path 7 toward lens 5 to display on screen 2. FIG. 1B shows a SLM 15 that has a surface 16 that includes an array of switchable reflective elements 17, 27, 37, and 47, each of these reflective elements is attached to a hinge 30. When the element 17 is in an ON position, a portion of the light from path 7 is reflected and redirected along path 6 to lens 5 where it is enlarged or spread along path 4 to impinge on the display screen 2 to form an illuminated pixel 3. When the element 17 is in an OFF position, the light is reflected away from the display screen 2 and, hence, pixel 3 is dark.

The on-and-off states of the micromirror control scheme, as that implemented in the U.S. Pat. No. 5,214,420 and in most conventional display systems, impose a limitation on the quality of the display. Specifically, applying the conventional configuration of a control circuit limits the gray scale gradations produced in a conventional system (PWM between ON and OFF states), limited by the LSB (least significant bit, or the least pulse width). Due to the ON-OFF states implemented in the conventional systems, there is no way of providing a shorter pulse width than the duration represented by the LSB. The least intensity of light, which determines the gray scale, is the light reflected during the least pulse width. The limited levels of the gray scale lead to a degradation of the display image.

Specifically, FIG. 1C exemplifies, as related disclosures, a circuit diagram for controlling a micromirror according to U.S. Pat. No. 5,285,407. The control circuit includes memory cell 32. Various transistors are referred to as “M*” where “*” designates a transistor number and each transistor is an insulated gate field effect transistor. Transistors M5, and M7 are p-channel transistors; transistors, M6, M8, and M9 are n-channel transistors. The capacitances, C1 and C2, represent the capacitive loads in the memory cell 32. The memory cell 32 includes an access switch transistor M9 and a latch 32a based on a Static Random Access switch Memory (SRAM) design. All access transistors M9 on a Row line receive a DATA signal from a different Bit-line 31a. The particular memory cell 32 is accessed for writing a bit to the cell by turning on the appropriate row select transistor M9, using the ROW signal functioning as a Word-line. Latch 32a consists of two cross-coupled inverters, M5/M6 and M7/M8, which permit two stable states that include a state 1 when is Node A high and Node B low, and a state 2 when Node A is low and Node B is high.

The control circuit, as illustrated in FIG. 1C, controls the mirrors to switch between two states, driving the mirror to either an ON or OFF deflected angle (or position) as shown in FIG. 1A. The minimum intensity of light controllable to reflect from each mirror element for image display, i.e., the resolution of gray scale of image display for a digitally controlled image display apparatus, is determined by the shortest length of time that the mirror is controllably held in the ON position. The length of time that each mirror is held an ON position is in turn controlled by multiple bit words.

FIG. 1D shows the “binary time intervals” when controlling micromirrors with a four-bit word. As shown in FIG. 1D, the time durations have relative values of 1, 2, 4, 8, which in turn define the relative brightness for each of the four bits where “1” is the least significant bit and “8” is the most significant bit. According to the control mechanism as shown, the minimum controllable differences between gray scales for showing different levels of brightness is a represented by the “least significant bit” that maintains the micromirror at an ON position.

For example, assuming n bits of gray scales, one time frame is divided into 2ⁿ−1 equal time periods. For a 16.7-millisecond frame period and n-bit intensity values, the time period is 16.7/(2ⁿ−1) milliseconds.

Having established these times for each pixel of each frame, pixel intensities are quantified such that black is a 0 time period, the intensity level represented by the LSB is 1 time period, and the maximum brightness is 2ⁿ−1 time periods. Each pixel's quantified intensity determines its ON-time during a time frame. Thus, during a time frame, each pixel with a quantified value of more than 0 is ON for the number of time periods that correspond to its intensity. The viewer's eye integrates the pixel brightness so that the image appears the same as if it were generated with analog levels of light.

For controlling deflectable mirror devices, the PWM applies data to be formatted into “bit-planes”, with each bit-plane corresponding to a bit weight of the intensity of light. Thus, if the brightness of each pixel is represented by an n-bit value, each frame of data has the n-bit-planes. Then, each bit-plane has a 0 or 1 value for each mirror element. According to the PWM control scheme described in the preceding paragraphs, each bit-plane is independently loaded and the mirror elements are controlled according to bit-plane values corresponding to the value of each bit during one frame. Specifically, the bit-plane according to the LSB of each pixel is displayed for 1 time period.

Micro-electromechanical system (MEMS) devices, such as the above described micromirror device, tend to be sensitive to external environmental conditions, including temperature, humidity, fine particle dust, vibration, and shock. Therefore, a MEMS device requires a MEMS package to protect the device and so that it can operate normally. Many patents related to such a MEMS package have been disclosed.

FIGS. 2A and 2B are diagrams which together show the configuration of a MEMS package disclosed in U.S. Pat. No. 5,610,625. The configuration that is disclosed includes a ring 53 for retaining a window 52 so that the window is kept at a certain distance from the modulation array 51 placed on a substrate 50. In this configuration, there are problems in that not only are the number of components and the number of connections associated with the ring 53 increased, but there is also a difficulty in preventing the adhesive materials from spreading out beyond the joinder areas thus adversely affects the light transmission and other performance characteristics of the device.

FIG. 3 is a diagram showing the configuration of a MEMS package disclosed in U.S. Pat. No. 5,650,915. In this configuration, two package substrates 65 and 66, which sandwich a lead finger 63 (i.e., a lead frame 64), are used in order to retain a cover member 62 a certain distance from a micro-circuit chip 61 placed on a heat spreader 60. The aforementioned configuration includes the cover member 62 and heat spreader 60, in addition to the two package substrates, making the structure more complex.

FIG. 4 is a diagram showing the structure of a MEMS package disclosed in U.S. Pat. No. 6,624,921. The configuration uses beads 73 in order to retain a window 72 a certain distance from the micromirror device 71 of a micromirror device chip 70. This configuration is also faced with the problem of an increase in the number of components due to including the beads 73.

### SUMMARY OF THE INVENTION

With the situation as described above in mind, the present invention aims at providing a MEMS package simply configured by eliminating a dedicated spacer member used for securing the distance between the MEMS device and window substrate.

A first embodiment of the present invention is an image projection system comprises a micro-electromechanical system (MEMS) package wherein the MEMS package further includes: a first substrate and a second substrate joined together at a joinder surface applied with a joinder material thereon to provide an internal space to contain and package a MEMS device therein, wherein at least one of the first and second substrate is configured to have a an inclined surface near the joinder surface.

In another embodiment, the present invention discloses a method for manufacturing an image display device by implementing a micro-electromechanical system (MEMS) device contained in a package formed by joining together two substrates, the method comprising: forming an inclined surface on at least one of the two substrates; depositing a joinder material on a joinder surface near the inclined surface, joining together the two substrates to form a joined substrate by placing one of the substrates onto the joinder surface f another substrate deposited with the joinder material; and applying a dicing process to divide the joined substrate into individual MEMS packages.

### BRIEF DESCRIPTION OF THE DRAWINGS

The present invention is described in detail below with reference to the following Figures.

FIGS. 1A and 1B are, respectively, a functional block diagram and a top view of a portion of a micromirror array implemented as a spatial light modulator used in a conventional display system disclosed in a prior art patent;

FIG. 1C is a circuit diagram showing a prior art circuit for controlling a micromirror under the ON and OFF states of a spatial light modulator;

FIG. 1D is diagram showing the binary time intervals for a four-bit gray scale;

FIGS. 2A and 2B are top and side view diagrams showing the configuration of a MEMS package according to a conventional technique;

FIG. 3 is a diagram showing the configuration of another MEMS package according to a conventional technique;

FIG. 4 is a diagram showing the configuration of yet another MEMS package according to a conventional technique;

FIG. 5 is a diagram, as viewed from a diagonal perspective, showing an exemplary configuration of a MEMS package according to a first preferred embodiment of the present invention;

FIG. 6 is a cross-sectional diagram showing an exemplary configuration of a MEMS package according to the first embodiment of the present invention;

FIG. 7 is a flow chart exemplifying the process of the package substrate as a part of the production process of a MEMS package, according to the first embodiment of the present invention;

FIGS. 8A through 8G are diagrams for describing each process of the flow chart shown in FIG. 7;

FIG. 9 is a flow chart exemplifying the production process of a MEMS package according to the first embodiment of the present invention;

FIGS. 10A through 10F are diagrams for describing each process of the flow chart shown in FIG. 9;

FIG. 11 is a diagram showing an exemplary modification of a method for applying an adhesive included in a MEMS package according to the first embodiment of the present invention;

FIG. 12 is a diagram exemplifying the relation between the reflection light reflected by an inclined surface in a MEMS package, according to the first embodiment of the present invention, and the reflection light reflected by a mirror device;

FIGS. 13A and 13B are diagrams together showing an exemplary configuration of a MEMS package according to a second preferred embodiment of the present invention;

FIG. 14 is a diagram showing an exemplary configuration of a MEMS package according to a third preferred embodiment of the present invention;

FIG. 15 is a diagram showing an exemplary configuration of a MEMS package according to a fourth preferred embodiment of the present invention;

FIG. 16 is a diagram showing an exemplary configuration of a MEMS package according to a fifth preferred embodiment of the present invention;

FIG. 17 is a diagram showing an exemplary configuration of a MEMS package according to a sixth preferred embodiment of the present invention;

FIG. 18 is a diagram showing an exemplary configuration of a MEMS package according to a seventh preferred embodiment of the present invention;

FIG. 19 is a diagram showing an exemplary configuration of a MEMS package according to an eighth preferred embodiment of the present invention;

FIG. 20 is a diagram showing an exemplary configuration of a MEMS package according to a ninth preferred embodiment of the present invention;

FIG. 21 is a diagram showing an exemplary configuration of a MEMS package according to a tenth preferred embodiment of the present invention;

FIG. 22 is a diagram showing an exemplary configuration of a MEMS package according to an eleventh preferred embodiment of the present invention; and

FIG. 23 is a diagram showing an exemplary configuration of a MEMS package according to a twelfth preferred embodiment of the present invention.

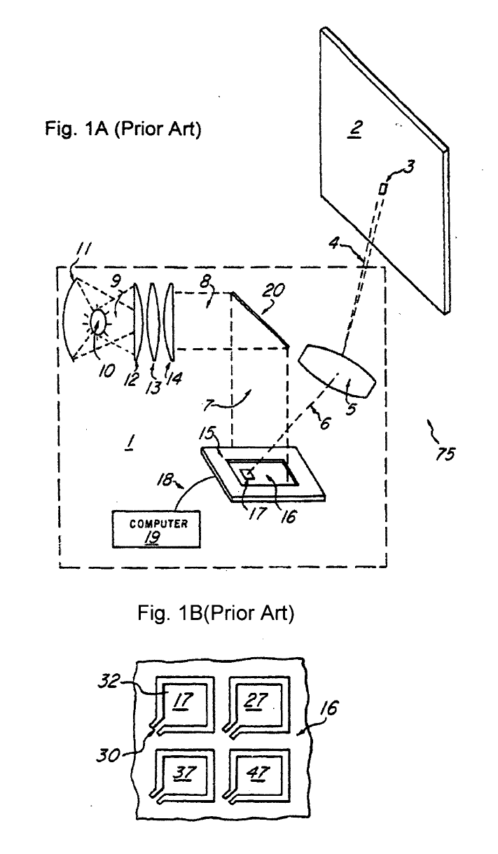

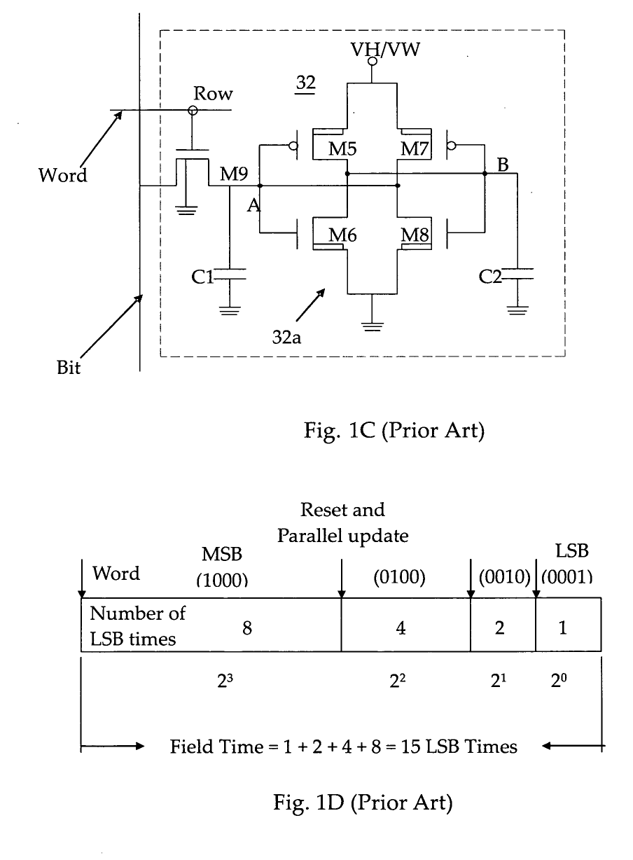

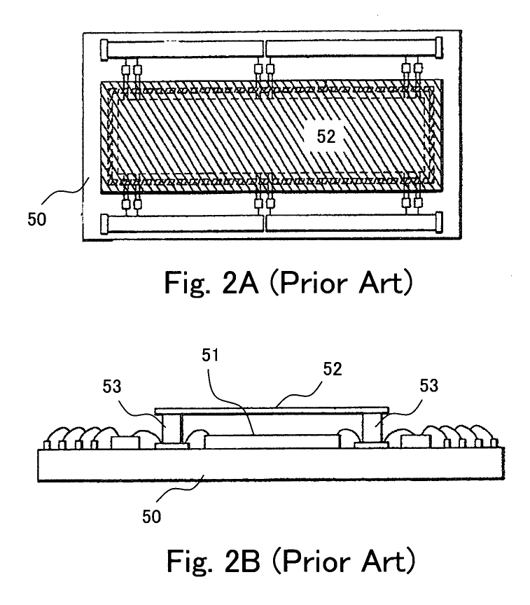

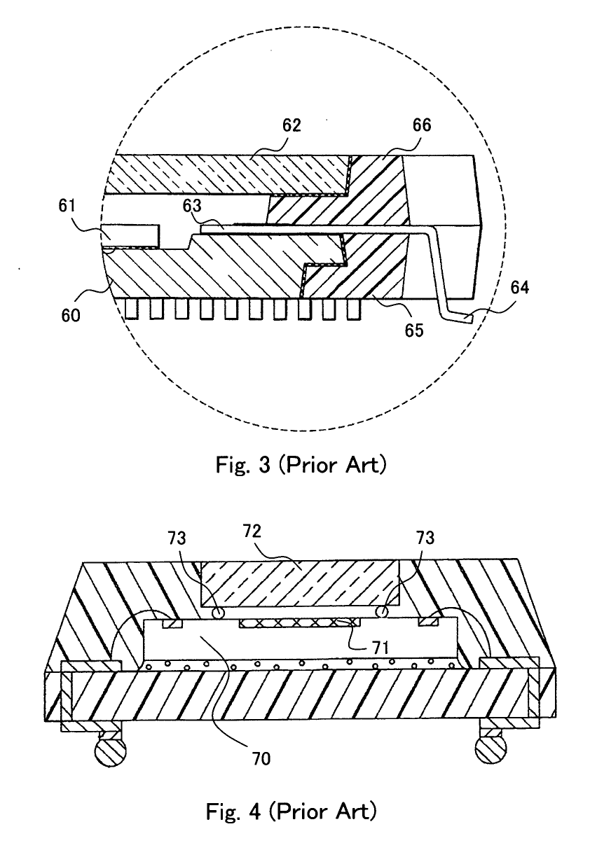

### DESCRIPTION OF THE PREFERRED EMBODIMENTS

The following is a description, in detail, of the preferred embodiment of the present invention with reference to the accompanying drawings.

### First Embodiment

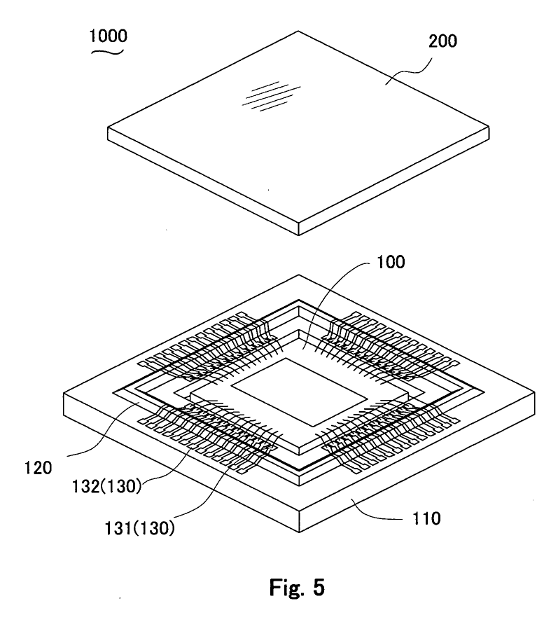

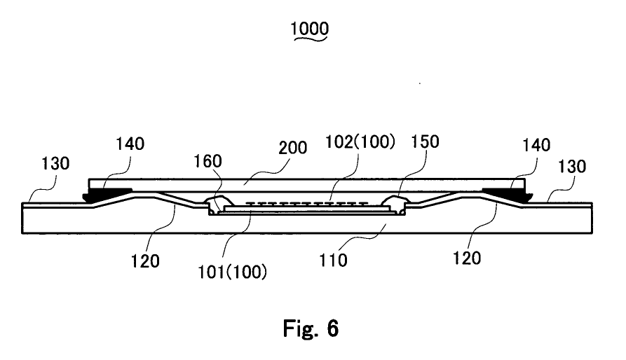

FIGS. 5 and 6 are diagrams showing an exemplary configuration of a MEMS package 1000 that packages a MEMS device inside the package. FIG. 5 is a diagonal view diagram of the MEMS package 1000, showing the package substrate 110 and the window substrate 200 separated, for better comprehension of the internal structure of the MEMS package 1000. FIG. 6 is a cross-sectional diagram showing the layer structure of the MEMS package 1000.

As exemplified in FIGS. 5 and 6, the MEMS package 1000 comprises a MEMS device 100, a package substrate 110 on which the MEMS device 100 is placed, an electrical connection unit 130, bonding wires 150, and a window substrate 200. For simplicity of description, the term, “MEMS package 1000” in this description includes the MEMS device 100 inside the packaging. Further, the term, “inside of package” indicates the space enclosing the MEMS device 100. In FIG. 6, for example, the space surrounded by the package substrate 110 and window substrate 200 is “inside of package”, as opposed to space “outside of package”.

The following is a brief description of the role of an individual constituent component.

To begin with, the MEMS device 100 is the object of the packaging and is, for example, a micromirror device in which a plurality of micromirror elements is arranged in an array (simply noted as “arrayed” hereinafter).

The micromirror device is a kind of spatial light modulator used for an image display apparatus and is capable of deflecting an illumination light incident from a light source using micromirror elements corresponding to the respective pixels of an image, thereby projecting a desired image.

Each micromirror element includes a mirror supported by an elastic hinge. The mirror is tilted by an electrostatic force generated between the mirror and an electrode placed under the mirror, in accordance with an electric signal from an external control circuit. The tilt angle of the mirror is, for example, between −12 degrees and +12 degrees, with the initial state of the mirror being zero (“0”) degrees. In this case, when the tilt angle of the mirror is +12 degrees, the mirror is in an ON state, deflecting the illumination light in the direction of a projection optical system. When the tilt angle of the mirror is −12 degrees, the mirror is in an OFF state, deflecting the illumination light away from the projection optical system.

The MEMS device 100 is positioned on the package substrate 110. The package substrate 110 includes a cavity for placing the MEMS device 100 and an inclined surface 120 used for joining the window substrate 200. A metalized layer 160, which is used for joining together the MEMS device 100 and package substrate 110, is formed inside of the cavity. The MEMS device 100 may be joined onto the metalized layer 160 by soldering. Alternatively, an adhesive, such as an epoxy-series adhesive and an ultraviolet hardening adhesive, and a low-melting point glass such as a fritted glass may be used for joining the MEMS device 100. Meanwhile, the cavity as shown in the figure is not necessarily required, and the MEMS device 100 may be placed instead within a step formed by the inclined surface 120.

The electrical connection unit 130 is formed as a pattern on the package substrate 110 and is utilized for securing an electrical connection between the inside and outside of the package. An internal electrode pad 131, used as the electrical connection point to the MEMS device 100, and an external electrode pad 132, used as the electrical connection point to the device external to the MEMS package 1000, are equipped on both sides of the electrical connection unit 130. In addition, the electrical connection unit 130 also radiates the heat from inside of the package to the outside. Alternatively, a thermal conductive member may be equipped, in addition to the electrical connection unit 130, so as to separate the function of electrical connection from that of heat transfer. These members are preferably made of aluminum, copper, gold, silver, tungsten magnesium, titanium, and the like.

The bonding wire 150 is a wire used to connect the electrode pad equipped on the top surface of the device substrate 101 of the MEMS device 100 to the internal electrode pad 131 equipped on the electrical connection unit 130. The bonding wire 150 secures the electrical connection between the device substrate 101 and electrical connection unit 130 and also conducts the heat of the device substrate 101. Also in this comprisal, a thermal conduction-use member may be separately placed, or the heat may be conducted by way of the above described metalized layer 160.

The window substrate 200 is joined to the package substrate 110 and is an optically transparent substrate tightly sealing the inside of the package. An anti-reflection coating is applied, commonly with MgF2, to the surface of the window substrate 200 in order to prevent extraneous light from influencing the display image. In addition to the reflection prevention method utilizing the difference in the refractive indexes of the MgF2, a method of preventing reflection by forming a fine micro-structure with pitch between the structural elements less than the wavelength of light has been recently proposed. While having a function as the gateway, i.e., the entrance and exit, for the light to and from the MEMS device 100, the window substrate 200 has the primary function of protecting the MEMS device 100 from dust and debris, which is generated in the substrate dicing process.

A joinder material 140 is placed on the inclined surface 120 of the package substrate 110. The joinder material 140 joins together the package substrate 110 and window substrate 200 without intervening directly on the joinder surface.

Note that while the configuration shown in FIG. 5 has the joinder surface that is formed as a rectangle surrounding inside of the package, such a configuration is arbitrary. The joinder surface may also be formed as a circular shape surrounding the inside of the package.

Note that the present specification document labels the contact surface between the package substrate 110 or window substrate 200 and the joinder material 140 as the “adhesion surface” and further labels the contact surface between the package substrate 110 and the window substrate 200 as the “joinder surface”.

Next is a description of the production process of the MEMS package 1000 according to the present embodiment.

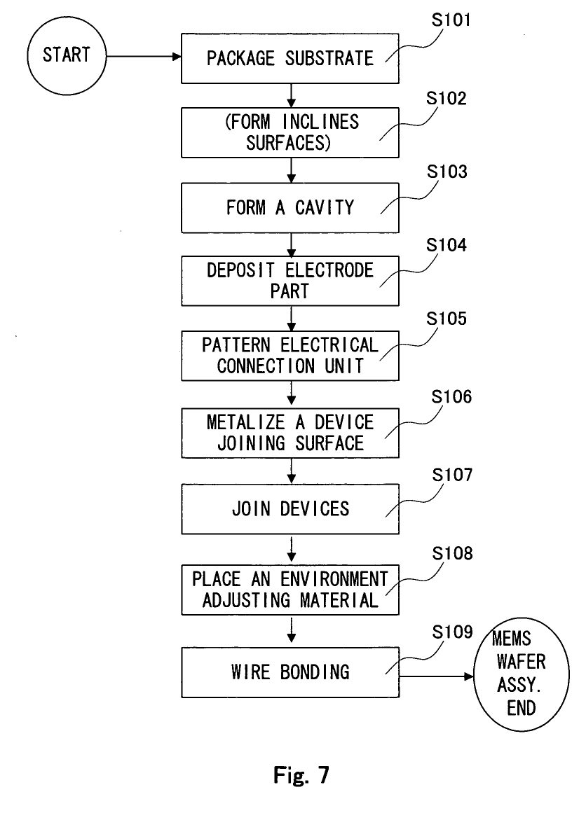

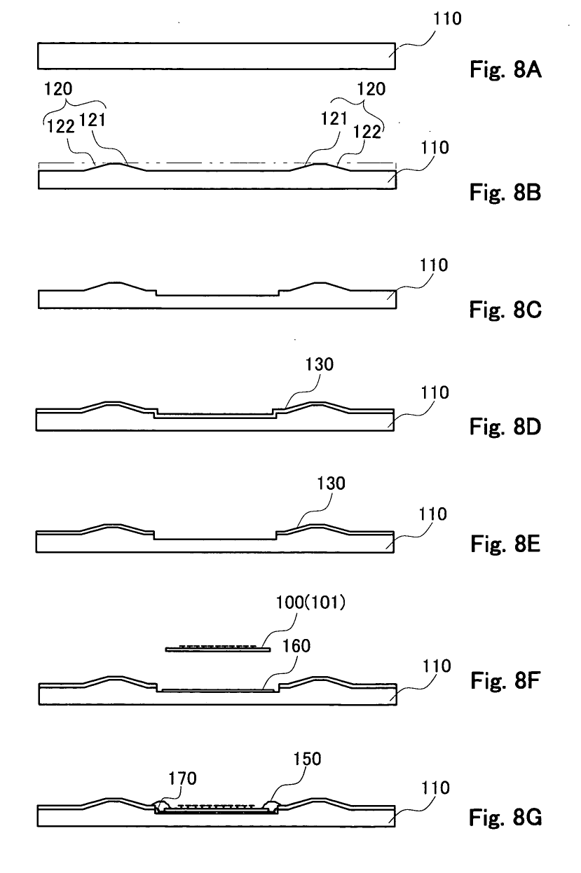

FIG. 7 is a flow chart exemplifying the process of the package substrate 110 as a part of the production process of the MEMS package 1000. FIGS. 8A through 8G are diagrams for describing each process of the flow chart shown in FIG. 7. The following is a description of the production process of the package substrate 110, in detail, with reference to FIG. 7 and FIGS. 8A through 8G.

First, in step S101, a package substrate 110 is prepared (refer to FIG. 8A). The package substrate 110 is composed of, for example, a glass substrate, a silicon substrate and a ceramic substrate. To prevent the MEMS device 100 from peeling off or breaking due to thermal expansion, the package substrate 110 is preferably composed of a material in which the coefficient of linear expansion is approximately the same as the material constituting the MEMS device 100. Further, in consideration of the above described thermal conduction, the package substrate 110 is preferably composed of a material with high thermal conductivity.

In S102, the inclined surface 120 is formed on the prepared package substrate 110 (refer to FIG. 8B). Specifically, the package substrate 110 is processed so as to leave a hill-like protrusion part (noted as “protrusion part” hereinafter) on both sides of a region (noted as “cavity part” hereinafter) in which a cavity is formed in step S103. The protrusion part plays the role of a spacer that is used for adjusting the distance between the MEMS device 100 and window substrate 200. The inclined surface 120 is formed as the two side surfaces of the protrusion part. The cavity side of each protrusion part is labeled the inside inclined surface 121, and the other inclined surface 120 is labeled as the outside inclined surface 122. Note that the inclined surface 120 can be formed by various methods such as grinding, sand blasting, chemical etching, and ultrasonic process (e.g., a honing). The method may be selected in consideration of the material used for the package substrate 110, the productivity of the method, and other factors.

In S103, a cavity for placing the MEMS device 100 between the two protrusion parts that have been formed in S102 is formed (refer to FIG. 8C). Note that the cavity may also be formed by using various methods such as sand blasting, chemical etching, ultrasonic processing, or the like, as in the case of forming the inclined surface 120.

In S104, a thin, electric conductive film is formed on the package substrate 110 as the precursor to forming the electrical connection unit 130 (refer to FIG. 8D). The thin film (simply noted as “film” hereinafter) is made of, for example, aluminum (Al). The film may be made of tungsten (W), aluminum (Al), gold (Au), silver (Ag), copper (Cu), magnesium (Mg), titanium (Ti), or other material with high thermal conductivity. The film may be formed by means of a physical vapor deposition vacuum deposition (PVD) such as a sputtering method and a vacuum deposition method.

In S105, the film formed in S104 is etched to form the pattern of the electrical connection unit 130 (refer to FIG. 8E). First, a photoresist is coated on the film by means of, for example, a spin coating method. Other methods include a spray method and a dipping method. Next, an etching mask is formed by exposing the photoresist using a mask for transferring the pattern of the electrical connection unit 130. Lastly, the pattern of the electrical connection unit 130 is formed by etching the etching mask.

Note that the protrusion part plays the role of a spacer used for supporting the window substrate 200 while maintaining the distance between itself and the MEMS device 100, as described above. Therefore, the side surfaces of the protrusion part may be configured to be a vertical surface. The MEMS package 1000 according to the present embodiment, however, is configured to form the side surface of the protrusion part as an inclined surface 120. The reason for it is to ease the transfer of the pattern onto the side surface.

Meanwhile, the height of the protrusion part is preferably as small as possible, since a variation in the distance between the mask and electrical connection unit 130 increases with the height of the protrusion part, thus decreasing the accuracy of transfer and of the pattern.

Next, in S106, a metalized layer 160 used for joining the MEMS device 100 onto the bottom surface of the cavity is formed (refer to FIG. 8F).

In S107, the MEMS device 100 is joined onto the metalized layer 160 using a solder (refer to FIGS. 8F and 8G).

In S108, an environment adjustment material 170 is placed inside of the cavity (refer to FIG. 8G). The environment adjustment material 170 absorbs the out-gas generated from the moisture inside of the cavity and from the joinder material 140. The environment adjustment material 170 is not limited to any particular material, and may be composed of a moisture absorption material, such as zeolite.

The last step, S108, is a wire bonding process. The electrode pad equipped on the top surface of the device substrate 101 is connected to an internal electrode pad 131 (not shown in drawing) equipped on the electrical connection unit 130 using the bonding wire 150 (refer to FIG. 8G). The bonding wire 150 is preferably made of gold (Au). The present embodiment shows the structure using a wire bonding; alternatively, the connection may use a land grip or ball grip, obtaining an electrical connection using a bump by extending the electrical connection unit to the outer edges of the cavity. With the above described process, the production process of the package substrate 110 is completed.

The following description labels the product, resulting from the above described processes in which the MEMS device 100 is placed on the package substrate 110 and the electrical connection unit 130 is formed, as the package substrate assembly 180.

Note that the initial form of the package substrate 110 is flat. However, this is arbitrary. Alternatively, a package substrate 110, for which a protrusion part is already formed by a molding or a sintering, may be prepared in S101. In such a case, the process for forming the inclined surface 120 (in S102) may be eliminated.

Further, FIG. 8G shows the diagram of only one piece of the MEMS device 100 joined onto the package substrate 110 for simplicity of description. In the actual production process, however, the package substrate 110 is designed to be a large scale substrate base so that a single substrate can produce a plurality of device-use package substrates, and thereby the productivity is improved.

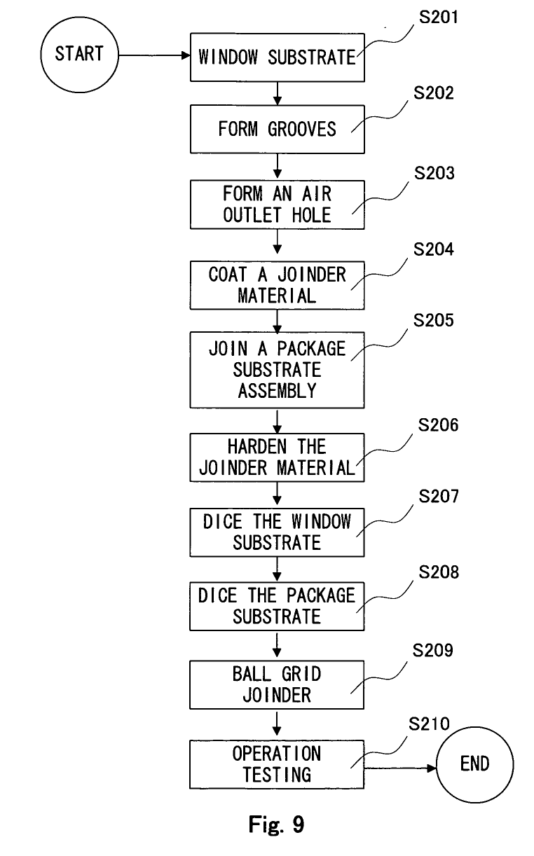

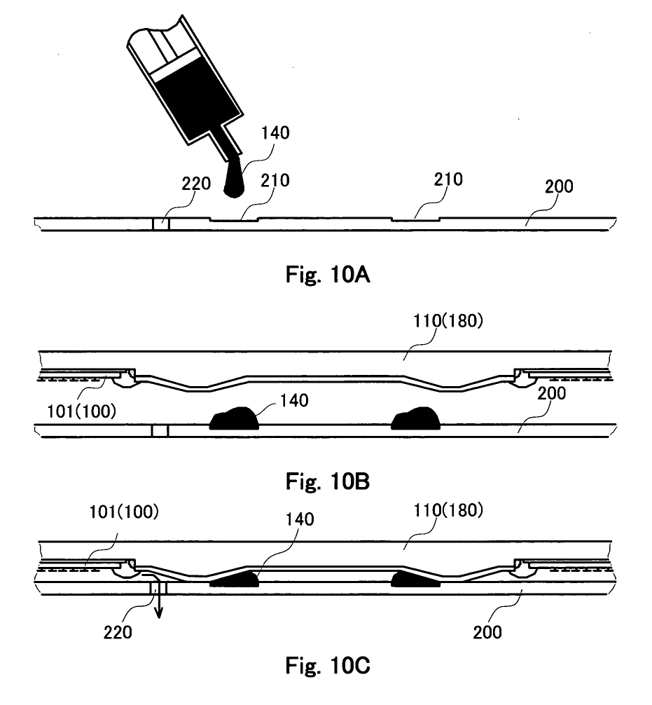

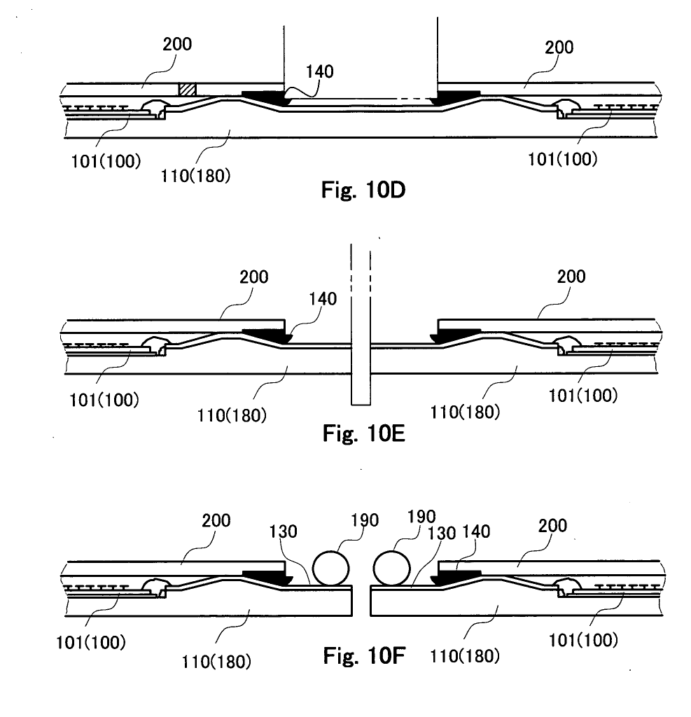

FIG. 9 is a flow chart exemplifying the production process of the MEMS package 1000 of joining together the package substrate assembly 180 and window substrate 200. FIGS. 10A through 10F are diagrams for describing each process of the flow chart shown in FIG. 9. The following is a description, in detail, of the production process of the MEMS package 1000 with reference to FIG. 9 and FIGS. 10A through 10F.

First, in S201, an optically transparent window substrate 200 is prepared. The material of the window substrate 200 is, for example, glass. Further, the top and bottom surfaces of the window substrate 200 may be coated with an anti-reflection (AR) coating produced by vapor-depositing magnesium fluoride, or the like, so as to eliminate extraneous reflection.

In S202, a groove 210 is formed on the window substrate 200 (refer to FIG. 10A). The groove 210 is utilized for positioning the joinder material 140 and plays the role of preventing failure when the window substrate 200 and package substrate assembly 180 are joined together, such as a positional shift, and preventing the joinder material 140 from touching an extraneous area. The groove 210 is formed at a position corresponding to the outside inclined surface 122 of the package substrate 110 when it is joined. Note that the groove 210 may also be formed at a position that is slightly shifted to the outside of the package from the upper position of the outside inclined surface 122. Such a configuration prevents the joinder material 140 from flowing to the joinder surface (i.e., the flat part of the protrusion part of the package substrate 110) between the window substrate 200 and package substrate 110, and instead allows the joinder material 140 to spread along the outside inclined surface 122.

In S203, an air outlet hole 220 is bored in the window substrate 200 on an as needed basis (refer to FIG. 10A). The air outlet hole 220 is formed as an air path between the substrates in order to ease the joining together of the package substrate assembly 180 and window substrate 200.

In S204, the joinder material 140 is placed in the groove 210 that has been formed in S202 (refer to FIGS. 10A and 10B). The joinder material 140 may be constituted by, for example, fritted glass, epoxy resin-series adhesive, solder, and the like. If the MEMS device 100 is a micromirror device, and if extraneous reflection occurs on the border surface between the window substrate 200 and joinder material 140, the reflection causes the contrast of the projected image to be reduced. Therefore, the refraction indexes of the joinder material 140 and window substrate 200 are preferably the same, in order to prevent extraneous reflection on the border surface. For example, if the window substrate 200 is made of a glass substrate, the joinder material 140 is preferably composed of fritted glass. Alternatively, the color of the joinder material 140 is preferred to be a dark color, such as black, for absorbing extraneous light.

In S205, the package substrate assembly 180 and window substrate 200 are joined together by using the joinder material 140 (refer to FIG. 10C). The joinder material 140, for example, fritted glass, is melted to become semi-liquid and is spread under pressure from the inclined surface 122 toward the outside as a result of the joinder material 140 coming in contact with the package substrate 110. The joinder material 140 does not intervene on the joinder surface between the package substrate 110 and window substrate 200. With this configuration, it is possible to prevent a shift in the distance between the MEMS device 100 and window substrate 200, caused by the joinder material 140 intervening on the joinder surface. Further, the air between the package substrate 110 and window substrate 200 is ventilated through the air outlet hole 220. Therefore, there is no possibility of the joinder position being shifted by extraneous pressure applied to both substrates during the process of being joined together.

After joining the window substrate 200, the air outlet hole 220 equipped in S203 is sealed. The sealant uses fritted glass, epoxy resin, ultraviolet hardening resin, or other similar material.

In S206, the joinder material 140 spread on the inclined surface 120 is hardened to fix the joined state of the package substrate assembly 180 and window substrate 200.

Step S207 is the first stage of the dicing process, in which only the window substrate 200 is cut (refer to FIG. 10D). The present embodiment is configured to equip the outside of the protrusion part with the outside inclined surface 122, and therefore, a space is created between the package substrate 110 and window substrate 200 on the outside of the package. This fact makes it possible cut only the window substrate 200 without damaging the electrical connection unit 130 on the package substrate 110. This configuration enables the window substrate 200 to be joined to the entire MEMS device 100 as one piece of wafer, instead of being joined onto individual MEMS device 100 on the package substrate 110 one by one, and to be divided into individual MEMS devices 100 after the aforementioned joinder.

Step S208 is the second stage of the dicing process, in which the package substrate 110 is cut to make a chip from the MEMS package 1000 (refer to FIG. 10E). The area in which the package substrate 110 is cut is a part of the area in which the electrical connection unit 130 is exposed by cutting the window substrate 200 in S207.

In S209, ball grids 190 are formed on the external electrode pad 132 of the electrical connection unit 130 in order to connect to an external device (refer to FIG. 10F).

Lastly in S210, the operation testing on each MEMS package 1000 is performed. This process completes the production process for the MEMS package 1000. The MEMS package 1000 according to the present embodiment is produced by the above described process.

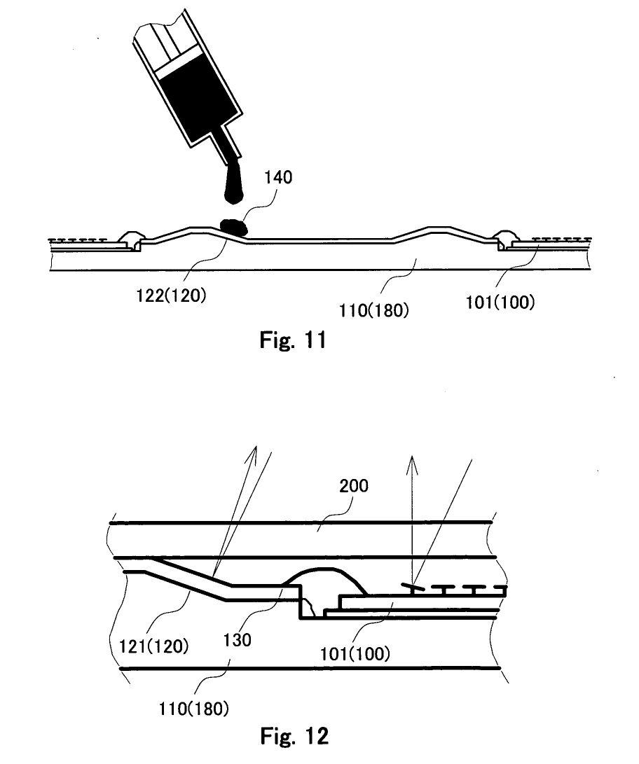

Note that the joinder material 140 is deposited on the window substrate 200 in FIG. 10A; however, it is not required for the joinder material 140 to be deposited on the side of the window substrate 200. Alternately, the joinder material 140 may be deposited on the inclined surface 120 of the package substrate 110, as shown in FIG. 11.

Further, if the MEMS device 100 is a micromirror device, the design of the inclined surface 120 needs to take into consideration the reflection of the illumination light incident to the inclined surface 120, as shown in FIG. 12. Specifically, the reflected light must be directed towards a direction other than the projection light path so that the reflection light reflected from the inclined surface 120 is not projected. Commonly, the ON light modulated by a micromirror is reflected perpendicularly to the package substrate, and the micromirror is in the maximum deflection state in this situation. Therefore, for example, if the inclination angle of the inclined surface 120 is configured to be no smaller than the maximum tilt angle of the mirror of the micromirror element, the extraneous light reflected on the inclined surface 120 will be reflected towards the illumination light path and not the projection light path.

The MEMS package 1000 according to the present embodiment is configured to form the protrusion part on the package substrate 110, thereby eliminating a spacer that is conventionally provided as a separate member from the substrate to secure the distance between the MEMS device 100 and window substrate 200. This configuration makes it possible to decrease the number of components and reduce the cost related to producing the package.

Further, the MEMS package 1000 according to the present embodiment is configured to form the side surface of a protrusion part as the inclined surface 120 and utilize it as the adhesion surface for the joinder material 140. This configuration separates the joinder surface from the adhesion surface. Since the joinder material 140 is not on the joinder surface, the distance between the MEMS device 100 and window substrate 200 can be accurately maintained. As a result, the top surface of the window substrate 200 can also be utilized as the surface for positioning the optical axis direction.

Further, the MEMS package 1000 according to the present embodiment is configured to use the inclined surface 120 as an adhesion surface, thereby making it possible to enlarge the area in which the joinder material 140 comes into contact with the package substrate 110. This configuration makes it possible to attain a strong joinder.

The MEMS package 1000 according to the present embodiment is configured to equip the window substrate 200 with the groove 210 used for positioning when depositing the joinder material 140. Further, the inclined surface 120 of the package substrate 110 makes it possible to manage the direction of the joinder material 140 spreading. This configuration stabilizes the positioning of the joinder material 140, making it possible to minimize variation in the joinder state between individual components.

### Second Embodiment

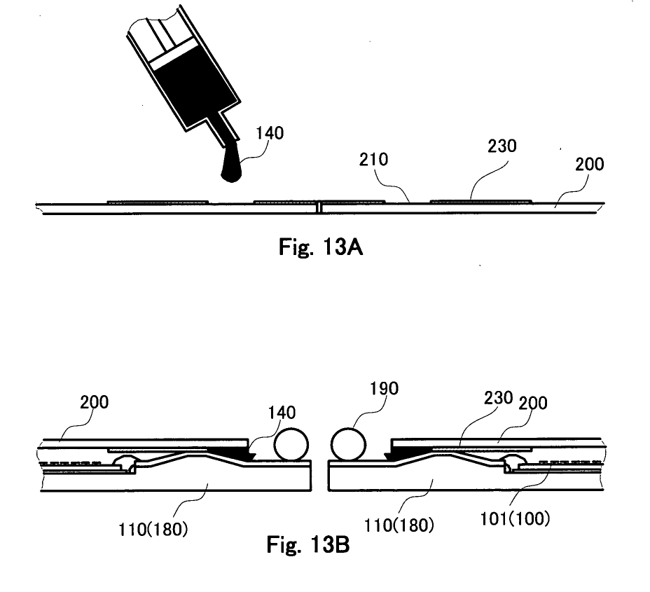

FIGS. 13A and 13B are diagrams for describing a second preferred embodiment. In contrast to the first embodiment, the present embodiment is configured to form a light-blocking layer 230 on the window substrate 200, used for preventing extraneous light inside of the package. Otherwise the configuration is similar to that of the first embodiment. The following describes the differences between the second embodiment and the first embodiment, with reference to FIGS. 13A and 13B.

As shown in FIGS. 13A and 13B, the light-blocking layer 230 is formed on some areas of the window substrate 200 which are not part of the designated light path. This configuration makes it possible utilize other areas not covered by the light-blocking layer 230 as a groove 210, utilized for positioning the joinder material 140, as opposed to actively forming a groove 210 by processing the window substrate 200 in the first embodiment, as described above.

Note that the material used for the light-blocking layer 230 may vary and may be selected in consideration of cost, durability, productivity, or other factors. Specifically, the material may be, for example, metallic thin film, painted film, resin film or a composite of them.

Further, the method for forming the light-blocking layer 230 may also vary. Possible methods includes a sputtering method, a vacuum deposition method, a screen printing method, and a method of adhesively attaching a separately produced light-blocking member onto a window substrate 200.

As described above, in addition to deriving the benefits of the first embodiment, the present embodiment prevents an increase in the temperature inside of the package caused by extraneous light entering the package and also prevents degradation in the contrast of an image due to extraneous light incident to the projection optical system.

### Third Embodiment

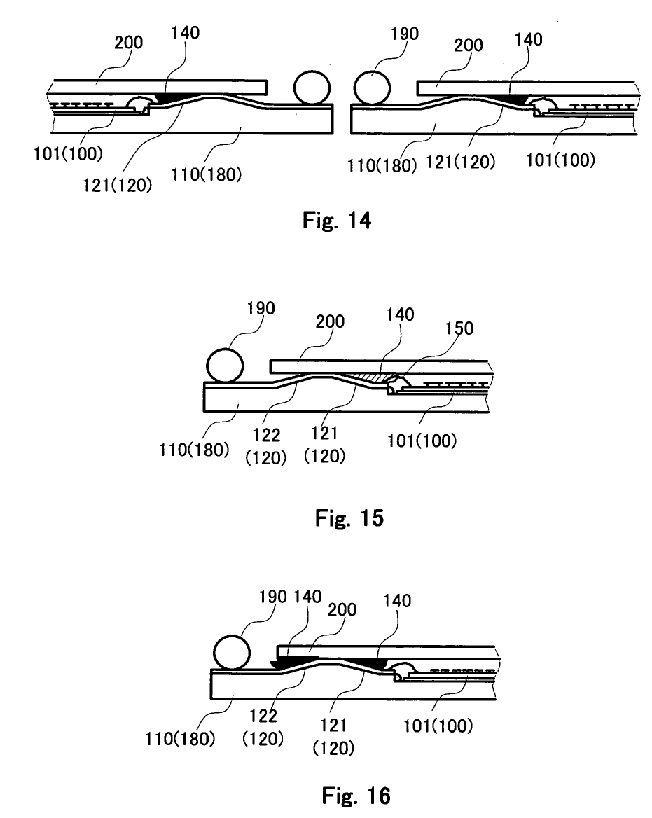

FIG. 14 is a diagram showing the structure of joining together a package substrate assembly 180 and a window substrate 200 according to a third preferred embodiment. The present embodiment results from changing the placement of the joinder material 140 in the first embodiment. Otherwise, it is similar to the configuration of the first embodiment. The following describes the difference from the first embodiment, with reference to FIG. 14.

The present embodiment is configured to join the package substrate assembly 180 and window substrate 200 using the joinder material 140 placed on the inside inclined surface 121 within the package.

As such, the present embodiment provides similar benefits as the first embodiment. Furthermore, modifications similar to the second embodiment can also be applied to the present embodiment.

By substituting a black, opaque adhesive for the joinder material 140, reflection of extraneous light coming from the nearby surface of the micromirror device inside of the package can be prevented, and thus a further benefit is realized.

### Fourth Embodiment

FIG. 15 is a diagram showing the structure of joining together a package substrate assembly 180 and a window substrate 200 according to a fourth preferred embodiment. As compared to the third embodiment, the present embodiment is configured to expand the surface area of adhesion using a joinder material 140. Otherwise, the configuration is similar to that of the third embodiment. The following describes the difference from the third embodiment, with reference to FIG. 15.

The present embodiment is configured to deposit the joinder material 140 inside of the package, as in the case of the third embodiment, and the joinder material 140 is deposited so that it spreads to the bonding wires 150. As a result, the bonding wires 150 are sealed by the joinder material 140, which is the difference from the third embodiment.

As such, in addition to deriving the benefits of the third embodiment, the present embodiment prevents the bonding wire 150 from peeling off or from contacting the window substrate 200, and also prevents extraneous light caused by the bonding wire 150. Furthermore, a modification that is similar to the second embodiment can also be applied to the present embodiment.

### Fifth Embodiment

FIG. 16 is a diagram showing the structure of joining together a package substrate assembly 180 and a window substrate 200 according to a fifth preferred embodiment. The present embodiment is configured to further add an adhesion surface to the configuration of the first embodiment. Otherwise, the configuration is similar to that of the first embodiment. The following is a description of the difference from the first embodiment, with reference to FIG. 16.

The present embodiment is configured to place a joinder material 140 on the inside inclined surface 121, in addition to the outside inclined surface 122, as shown in FIG. 16.

Note that, for the present embodiment, the joinder material 140 may be initially deposited on both the inside inclined surface 121 and the outside inclined surface 122, or may initially be deposited on the flat part on top of the protrusion part. If the joinder material 140 is placed on the flat part, the two substrates are pressed together with sufficient pressure to spread the joinder material 140 over both inclined surfaces 120, so as to prevent the joinder material 140 from remaining on the flat part after the joinder material 140 is hardened.

As such, the present embodiment is configured to expand the adhesion surface area, thereby making it possible to strengthen the adhesion between the package substrate assembly 180 and window substrate 200, while also deriving the benefits of the first embodiment. Furthermore, a modification that is similar to the second embodiment can also be applied to the present embodiment.

### Sixth Embodiment

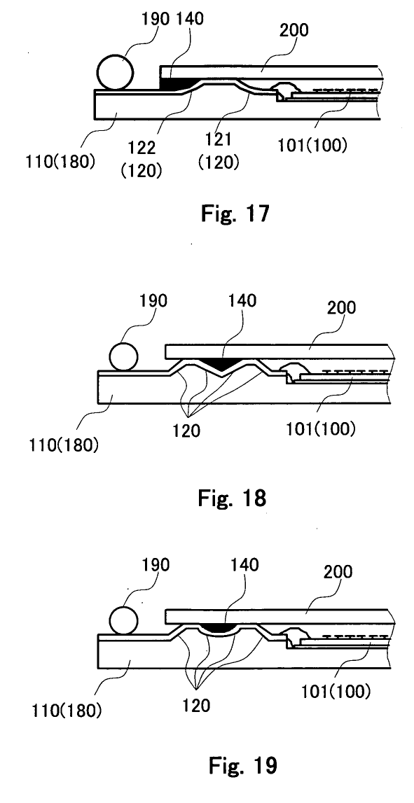

FIG. 17 is a diagram showing the structure of joining together a package substrate assembly 180 and a window substrate 200 according to a sixth preferred embodiment. In the present embodiment, the form of the protrusion part is different from that of the first embodiment. Otherwise, the configuration is similar to that of the first embodiment. The following is a description of the difference from the first embodiment, with reference to FIG. 17.

The present embodiment is configured such that the side surfaces of the protrusion part formed on the package substrate 110 is concavely curved, instead of being a flat surface. This difference increases the surface area of the outside inclined surface 122 (i.e., the inclined surface 120) to be utilized as an adhesion surface.

As such, the present embodiment makes it possible to more strongly join together the package substrate assembly 180 and window substrate 200 by virtue of the expanded adhesion surface area, while deriving the benefits of the first embodiment. Furthermore, a modification that is similar to the second embodiment can also be applied to the present embodiment.

Note that the side surface of the protrusion part formed on the package substrate 110 may alternatively be convexly curved, in contrast to the configuration shown in FIG. 17. Such a modification improves the accuracy in the pattern forming of the electrical connection unit 130 on the inclined surface 120.

### Seventh Embodiment

FIG. 18 is a diagram showing the structure of joining together a package substrate assembly 180 and a window substrate 200 according to a seventh preferred embodiment. In the present embodiment, the form of the protrusion part and the placement of the joinder material 140 is different from those of the first embodiment. Otherwise, the configuration is similar to that of the first embodiment. The following is a description of the difference from the first embodiment, with reference to FIG. 18.

The present embodiment is configured to form two straight-line protrusion parts on both sides of the cavity part, as shown in FIG. 18. Further, the joinder material 140 is placed in the space between the two protrusion parts and also the window substrate 200.

As such, in the present embodiment, there are actually four adhesion surfaces on the package substrate 110, i.e., two for both sides of the cavity part. This configuration provides a more stable adhesion between the package substrate assembly 180 and the window substrate 200, while also deriving the benefits of the first embodiment. The number of protrusion parts is arbitrary, and the forming of a plurality thereof makes it possible to derive a similar benefit. Furthermore, a modification that is similar to the second embodiment can also be applied to the present embodiment.

### Eighth Embodiment

FIG. 19 is a diagram showing the structure of joining together a package substrate assembly 180 and a window substrate 200 according to an eighth preferred embodiment. In the present embodiment, the form of the side surface of the protrusion part is different from that of the seventh embodiment. Otherwise, the configuration is similar to that of the seventh embodiment. The following is a description of the difference from the seventh embodiment, with reference to FIG. 19.

As shown in FIG. 19, the present embodiment is configured such that the two facing side surfaces of the protrusion parts are concavely curved, instead of being a flat surface. Such a change enlarges the surface area of an inclined surface 120 to be utilized for an adhesion surface.

As such, while also realizing the benefits of the seventh embodiment, the present embodiment is configured to enlarge the adhesion surface area, thereby providing a stronger adhesion between the package substrate assembly 180 and window substrate 200. Furthermore, a modification that is similar to the second embodiment can also be applied to the present embodiment.

### Ninth Embodiment

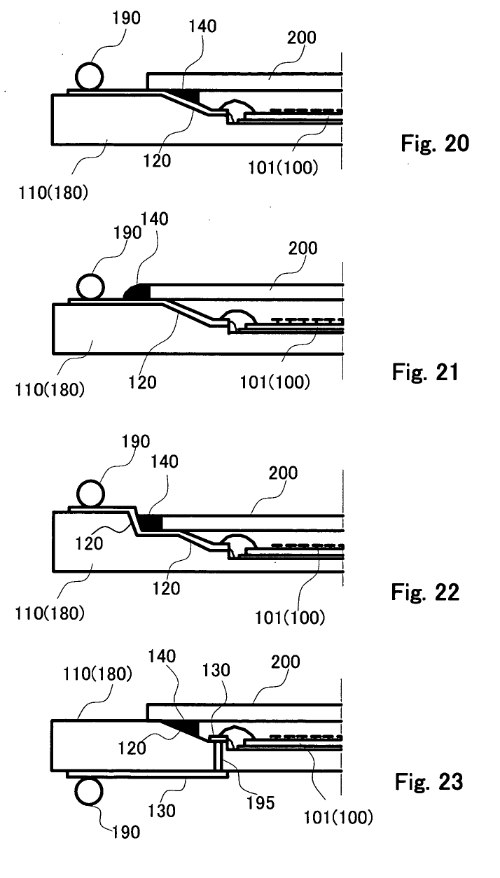

FIG. 20 is a diagram showing the structure of joining together a package substrate assembly 180 and a window substrate 200 according to a ninth preferred embodiment. The protrusion part of the first embodiment is changed to a step having an inclined surface 120 in the present embodiment. Otherwise, the configuration is similar to that of the first embodiment. The following is a description of the difference from the first embodiment, with reference to FIG. 20.

The present embodiment is configured to form a step having only one inclined surface 120 on the package substrate 110, instead of a protrusion part with two inclined surfaces, as in the first embodiment. Further, the joinder material 140 is placed on the inclined surface 120 that forms the step. Such a change makes it possible to simplify the processing of the package substrate 110.

Further, in the present embodiment there is no space between the package substrate 110 and window substrate 200 on the outside of the package. Therefore, it is necessary to apply a dicing process to the window substrate 200 before the substrates are joined together, unlike the case of the first embodiment. In this case, it is possible to obtain a larger number of window substrates 200 from one piece of wafer than when dicing after the substrates are joined together, decreasing the unit price of the component associated with the window substrate 200.

As such, the present embodiment also provides similar benefits as the first embodiment. Further, a modification that is similar to the second embodiment can also be applied to the present embodiment.

### Tenth Embodiment

FIG. 21 is a diagram showing the structure of joining together a package substrate assembly 180 and a window substrate 200 according to a tenth preferred embodiment. In the present embodiment, the position where the joinder material 140 is deposited is different from the ninth embodiment. Otherwise, the configuration is similar to that of the ninth embodiment. The following is a description of the difference from the ninth embodiment, with reference to FIG. 21.

The present embodiment is configured to deposit the joinder material 140 outside of the package. Such a change makes it possible to deposit the joinder material 140 after the package substrate 110 and window substrate 200 are in contact with each other. Note that in this case, a dicing process needs to be applied to the window substrate 200 before the substrates are joined together.

The present embodiment also makes it possible to eliminate the spacer member, thus reducing the cost related to producing the package since there is a decrease in the number of components.

In addition, in this embodiment, there is no joinder material 140 on the surface between the package substrate 110 and window substrate 200, and therefore, the distance between the MEMS device 100 and window substrate 200 can be accurately secured. This, in turn, prevents problems, such as the bonding wire 150 coming in contact with the window substrate 200. Further, the present embodiment may equip a light-blocking layer 230 on the window substrate 200.

### Eleventh Embodiment

FIG. 22 is a diagram showing the structure of joining together a package substrate assembly 180 and a window substrate 200 according to an eleventh preferred embodiment. The protrusion part of the first embodiment is changed to a two-stage step having two inclined surfaces 120 in this present embodiment. Otherwise, the configuration is similar to that of the first embodiment. The following is a description of the difference from the first embodiment, with reference to FIG. 22.

The present embodiment is configured with a two-stage step having two inclined surfaces 120 on the package substrate 110, in place of the protrusion part in the first embodiment. Further, the window substrate 200 is supported by part of the flat surface between the two inclined surfaces 120, and the joinder material 140 is deposited on the other part of the flat surface. Such a change makes it possible to deposit the joinder material 140 after placing the window substrate 200 on the package substrate 110. Further, the joinder material 140 is actually surrounded by three surfaces: the flat surface formed between the two inclined surfaces 120, the side surface of the window substrate 200 and the upper inclined surface 120. This configuration makes it possible to stabilize the placement position of the joinder material 140 and to secure a larger surface area for adhesion.

The present embodiment is further configured to bury the window substrate 200 in the package substrate 110. Therefore, it is necessary to apply a dicing process to the window substrate 200 before the substrates are joined, unlike the case of the first embodiment. In this case, it is possible to obtain a larger number of window substrates 200 from one piece of wafer than when dicing the window substrate 200 after the substrates are joined together, decreasing the unit price of components associated with the window substrate 200.

As described above, also the present embodiment eliminates the spacer member and decreases the number of components, thereby making it possible to reduce the cost related to producing the package.

In addition, there is no joinder material 140 intervening on the surface between the package substrate 110 and window substrate 200, and therefore, the distance between the MEMS device 100 and window substrate 200 can be accurately secured. This, in turn, prevents problems such as the bonding wire 150 contacting the window substrate 200. Further, increasing the adhesion surface area makes it possible to more securely and adhesively join together the package substrate assembly 180 and window substrate 200. Also, the present embodiment may equip a light-blocking layer 230 on the window substrate 200. Note that the present embodiment may also be applied to a configuration in which wireless bonding is employed.

### Twelfth Embodiment

FIG. 23 is a diagram showing the structure of joining together a package substrate assembly 180 and a window substrate 200 according to a twelfth preferred embodiment. In the present embodiment, the protrusion part of the first embodiment is changed to a step having an inclined surface 120 and electrically connected to an electrical connection unit formed on the lower surface of the package substrate through a hole. Otherwise, the configuration is similar to that of the first embodiment. The following is a description of the difference from the first embodiment, with reference to FIG. 23.

The present embodiment is configured to form a step having only one inclined surface 120 on the package substrate 110, as shown in FIG. 23. Such a change simplifies the processing of the package substrate 110.

Further, electrical connection units 130 are placed in two areas, on a flat surface, including the internal electrode pad 131, on the top surface of the package substrate 110 and on a flat surface of the bottom surface (i.e., the surface to which the window substrate 200 is not joined) of the package substrate 110. The electrical connection between the electrical connection unit 130 inside of the package and the electrical connection unit 130 outside of the package is secured through a hole 195 near the internal electrode pad 131. In this configuration, the electrical connection unit 130 is formed only on flat surfaces, improving the transfer accuracy of a mask when forming the electrical connection unit 130 and improving the pattern accuracy of the electrical connection unit as a result.

Further, in the present embodiment, there is no space between the package substrate 110 and window substrate 200 on the outside of the package, unlike the case of the first embodiment. However, there is no electrical connection unit 130 intervening between the package substrate 110 and window substrate 200 and therefore, even if the package substrate 110 and window substrate 200 are joined together, there is no possibility of damaging the electrical connection unit 130 when a dicing process is applied to the window substrate 200. Therefore, the package substrate 110 and window substrate 200 can be joined together in units of wafer, as in the case of the first embodiment, and thereby, the production process can be simplified.

As such, the present embodiment provides similar benefits as the first embodiment. Further, a modification similar to that of the second embodiment can also be applied to the present embodiment.

The present invention is configured to eliminate a dedicated spacer member used for securing the distance between a MEMS device and a window substrate, thereby enabling a more simply configured MEMS package.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

What is claimed is:

1. An image projection system comprises a micro-electromechanical system (MEMS) package wherein the MEMS package further comprising:
a first substrate and a second substrate joined together at a joinder surface applied with a joinder material thereon to provide an internal space to contain and package a MEMS device therein, wherein at least one of the first and second substrate is configured to have a an inclined surface near the joinder surface.

2. The image projection system according to claim 1, wherein:
at least one of the first and second substrate has a groove, a step, or a cavity part for applying the joinder material therein.

3. The image projection system according to claim 2, further comprising:
a light-blocking layer or light-blocking member on a part of one of the first or second substrate to block a light from projecting to the groove, step of cavity applied with the joinder material.

4. The image projection system according to claim 1, wherein:
the joinder material is placed on the inclined surface to contact and join the first and the second substrates near the joinder surface.

5. The image projection system according to claim 1, wherein:
The first and second substrates are vertically stacked and joined together on the joinder surface surrounding the horizontal plane of the substrates configured as a circular-shaped joinder surface.

6. The image projection system according to claim 1, further comprising:
an electrical connection unit disposed on the inclined surface for connecting an electric contact disposed inside of the internal space of the package and an electric contact outside of the package, is formed on the inclined surface.

7. The image projection system according to claim 1, wherein:
the substrate formed with the inclined surface further includes a flat surface immediately next to the inclined surface wherein the flat surface is further covered with conductive lines ready for connecting to electrical terminals disposed on the MEMS device contained in the internal space of the package.

8. The image projection system according to claim 1, wherein:
the joinder material is disposed on the inclined surface to join the first and second substrates wherein the inclined surface is surrounded by the joinder surface to provide and seal the internal space of the package and the inclined surface is further covered with bonding wire pads for connecting to bonding wires disposed in the internal space inside of the package.

9. The image projection system according to claim 1, wherein:
the joinder material has a dark color.

10. The Image projection system according to claim 1, wherein:
the MEMS device contained in the internal space inside the package is a micromirror device comprising a plurality of micromirrors.

11. The image projection system according to claim 10, wherein:
the inclined surface disposed near the joinder surface has a surface inclined angle different from a deflecting angle of the micromirrors.

12. The image projection system according to claim 10, wherein:
the inclined surface disposed near the joinder surface has a surface inclined angle equal to or greater than a deflecting angle of the micromirrors relative to one of the first and second substrates disposed with the micromirror device.

13. The image projection system according to claim 1, wherein:
the first substrate further comprises a cavity with side surfaces forming a step for accommodating and placing the second substrate on the step, and the first substrate and second substrates are joined together with the joinder material applied to the side surfaces of the step and sidewalls of the second substrate.

14. The image projection system according to claim 1, wherein:
one of the first or second substrates further includes multiple adjacent inclined surfaces configured as a mountain-shaped protrusion, wherein a top surface of the mountain-shaped protrusion constitutes the joinder surface for joining the first and second substrates together.

15. The image projection system according to claim 14, wherein:
the joinder material joining together the two substrates is placed on at least one of the two adjacent inclined surfaces of the mountain-shaped protrusion.

16. The image projection system according to claim 14, wherein:
One of the first or second substrates further includes at least two adjacent mountain-shaped protrusions forming a mountains-and-valley profile wherein top surfaces of the mountain-shaped protrusions constitute the joinder surface for joining the first and second substrates thereon.

17. A method for manufacturing an image display device by implementing a micro-electromechanical system (MEMS) device contained in a package formed by joining together two substrates, the method comprising:
forming an inclined surface on at least one of the two substrates;
depositing a joinder material on a joinder surface near the inclined surface;
joining together the two substrates to form a joined substrate by placing one of the substrates onto the joinder surface of another substrate deposited with the joinder material; and
applying a dicing process to divide the joined substrate into individual MEMS packages.

18. The method according to claim 17, wherein:
the step of forming the inclined surface further comprises a step of mechanically or chemically removing a part of at least either one of the two substrates.

19. The method according to claim 17, wherein:
The step of forming the inclined surface further comprises a step of applying a mold process on at least one of the two substrates.

20. The method according to claim 17, further comprising:
forming an electrical connection unit for he MEMS device on the inclined surface after the step of forming the inclined surface.

21. The method according to claim 17, further comprising:
forming a through hole in at least either one of the two substrates, prior to or right after the step of forming the inclined surface, and
closing the through hole right after the step of joining the substrates together as a joined substrate.
